(19) United States
(12) Patent Application Publication
(10) Pub. No.: US 2022/0196580 A1
(43) Pub. Date: Jun. 23, 2022

(54) DEFECT INSPECTION METHODS OF SEMICONDUCTOR WAFERS

(71) Applicant: GLOBALFOUNDRIES U.S. Inc., Santa Clara, CA (US)

(72) Inventors: HAIZHOU YIN, Halfmoon, NY (US); CHENLONG MIAO, Malta, NY (US); SHAO WEN GAO, Clifton Park, NY (US); MICHAEL WOJTOWECZ, Ballston Spa, NY (US); TAMER DESOUKY, Saratoga Springs, NY (US)

(21) Appl. No.: 17/128,200

(22) Filed: Dec. 21, 2020

(51) Int. Cl. G01N 23/2251; G01N 23/18

(52) U.S. Cl. CPC G01N 23/2251; G01N 2223/6116; G01N 23/18

(57) ABSTRACT

The embodiments herein relate to defect inspection methods of semiconductor wafers during the manufacturing process. According to an aspect of the present disclosure, a defect inspection system is provided. The defect inspection system includes a first inspection system, pattern simulator software, and a second inspection system. The first inspection system is capable of determining a plurality of defect locations on an article. The pattern simulator software is capable of generating a set of simulated pattern features from the plurality of defect locations. The second inspection system is capable of providing a higher graphical resolution of defects than the first inspection at the defect locations corresponding to the set of simulated pattern features.

### FIELD OF THE INVENTION

The disclosed subject matter relates generally to the field of inspection of articles, and more particularly to defect inspection methods and systems thereto for semiconductor wafers during the manufacturing process.

### BACKGROUND

With technological advances in the semiconductor integrated circuit (IC) industry, there is a continuing demand for device miniaturization with higher circuit packing densities for performance improvements. Manufacturing ICs at such minute dimensions adds complexity to various stages of the manufacturing process.

Defect inspection steps are introduced at the various manufacturing stages for engineering analysis and line monitoring purposes to improve production yield and product reliability. If a defect can be detected early, the cause of the defect can be determined and corrected before a significant number of defective ICs are manufactured.

Effects of device miniaturization include smaller defect sizes and greater defect counts. The associated cost of such inspections, both in terms of expense and time, is therefore expected to increase exponentially. Accordingly, it is desirable to provide defect inspection methods and systems thereto for semiconductor wafers during the manufacturing process to establish an effective defect review process.

### SUMMARY

To achieve the foregoing and other aspects of the present disclosure, defect inspection methods and systems thereto for semiconductor wafers during the manufacturing process are presented.

According to an aspect of the present disclosure, a defect inspection system is provided. The defect inspection system includes a first inspection system, pattern simulator software, and a second inspection system. The first inspection system is capable of determining a plurality of defect locations on an article. The pattern simulator software is capable of generating a set of simulated pattern features from the plurality of defect locations. The second inspection system is capable of providing a higher graphical resolution of defects than the first inspection at the defect locations corresponding to the set of simulated pattern features.

According to another aspect of the present disclosure, a defect inspection method is provided. The defect inspection method includes determining a plurality of defect locations on an article and generating a set of simulated pattern features from the plurality of defect locations. A subset of simulated pattern features is selected from the set of simulated pattern features. The article is inspected at the defect locations corresponding to the subset of simulated pattern features.

According to yet another aspect of the present disclosure, a defect inspection method is provided. The defect inspection method includes performing a first inspection on an article to determine a plurality of defects and obtain position coordinates thereto. The position coordinates of the plurality of defects are correlated to a circuit layout of the article. A simulation is performed on the circuit layout at the corresponding defect position coordinates to obtain a set of simulated pattern features. A subset of the simulated pattern features is selected from the set of simulated pattern features. A second inspection is performed on the article at the position coordinates corresponding to the subset of simulated pattern features.

### BRIEF DESCRIPTION OF THE DRAWINGS

The embodiments of the present disclosure will be better understood from a reading of the following detailed description, taken in conjunction with the accompanying drawings:

FIG. 1 is a flow chart illustrating a method for defect inspection of semiconductor wafers during the manufacturing process, according to an embodiment of the disclosure.

FIG. 2 illustrates a defect inspection system for semiconductor wafers, according to an embodiment of the disclosure.

For simplicity and clarity of illustration, the drawings illustrate the general manner of construction, and certain descriptions and details of well-known features and techniques may be omitted to avoid unnecessarily obscuring the discussion of the described embodiments of the device.

Additionally, elements in the drawings are not necessarily drawn to scale. For example, the dimensions of some of the elements in the drawings may be exaggerated relative to other elements to help improve understanding of embodiments of the device.

The same reference numerals in different drawings denote the same elements, while similar reference numerals may, but do not necessarily, denote similar elements.

### DETAILED DESCRIPTION

The present disclosure relates to defect inspection methods and systems thereto for semiconductor wafers during the manufacturing process.

At various manufacturing stages in the manufacturing process, a wafer may be inspected for defects for engineering analysis and/or line monitoring purposes. For example, after a lithography process, the wafer may be inspected for defects to ensure the mask pattern printed on the wafer is consistent with the mask. The mask is fabricated according to circuit layouts of the integrated circuits of the semiconductor chips that are to be fabricated on the wafer. The circuit layouts may be provided in the form of a GDSII format or an OASIS format.

A circuit layout is a two-dimensional representation of a three-dimensional element or component of an integrated circuit. The circuit layout may include planar geometric shapes, such as patterns of metal, dielectric, or semiconductor elements that correspond to patterns of various semiconductor components.

The patterns of the circuit layout may be translated to a mask, also referred to as a reticle, at a mask fracturing stage. During a lithography process, the circuit layout pattern in the mask is transferred or printed on a layer of photoresist coated on the wafer. The circuit layout pattern printed on the photoresist is subsequently used as a mask for a subsequent process, such as an etching process, to form the circuit layout pattern on the wafer.

Potential defects may be introduced in the lithography process and may include bridging pattern features, missing pattern features, particles, residues, and collapsed pattern features. These types of defects adversely impact production yield and product reliability as the subsequent processing step, such as an etching process or an implantation process, relies on the mask pattern printed to define the circuit patterns on the wafer. Other manufacturing processes that may include a defect inspection step include an etch process or a deposition process.

Defects may be categorized into random or systematic defects. Random defects occur in random locations that are inconsistent with normal process variations and the possibility of them occurring repeatedly in a specific location is low. An example of a random defect is a physical/particle defect that becomes attached to a wafer surface.

Systematic defects, on the other hand, generally occur due to the interaction of the circuit layout and the manufacturing process. The systematic defects are defects that are likely to occur in combination with a particular circuit layout pattern and a particular process. The systematic defects may be repeatable, provided being applied with the same processing conditions, and may occur at the positions of the same circuit layout pattern that has been printed on the wafer. An example of a systematic defect is a pattern defect that may include, but not limited to, open defects such as broken pattern features and shorted defects such as bridged pattern features.

Therefore, while the occurrence of random defects cannot be generally predicted based on the circuit layout, the systematic defects may be identified by employing a defect inspection methodology that detects a defect based on the circuit layout of the integrated circuit.

There are several types of defect inspection systems to detect defects on the wafer, including optical inspection systems and electron beam (e-beam) inspection systems. Optical inspection systems, such as a bright-field inspection system and a dark-field inspection system, are often used to inspect an entire wafer surface for defects due to their relatively high throughputs. However, the graphical resolution of such optical inspection systems is limited and may be insufficient for identifying defects in the nanoscale dimensions due to limitations of the optical inspection technology.

E-beam inspection systems, on the other hand, are capable of providing high graphical resolution of defects and are often used to identify defects that are too small for optical inspections. Scanning electron microscopy (SEM) and transmission electron microscopy (TEM), for example, are e-beam inspection systems. The e-beam inspection systems are capable of providing graphical resolution to the order of nanometers or smaller and can further perform defect mode inspections, such as voltage contrast, to detect defects that cannot be revealed in an optical review. Even though the e-beam inspection systems are able to provide much higher graphical resolutions than optical inspection systems, the low throughputs of e-beam inspection systems have been generally relinquished for mainly engineering analysis, rather than for line monitoring purposes.

Various embodiments of the present disclosure are now described in detail with accompanying drawings. It is noted that like and corresponding elements are referred to by the use of the same reference numerals. The embodiments disclosed herein are exemplary, and not intended to be exhaustive or limiting to the disclosure. Certain structures may be conventionally fabricated, for example, using known processes and techniques, and specifically disclosed processes and methods may be used to achieve individual aspects of the present disclosure.

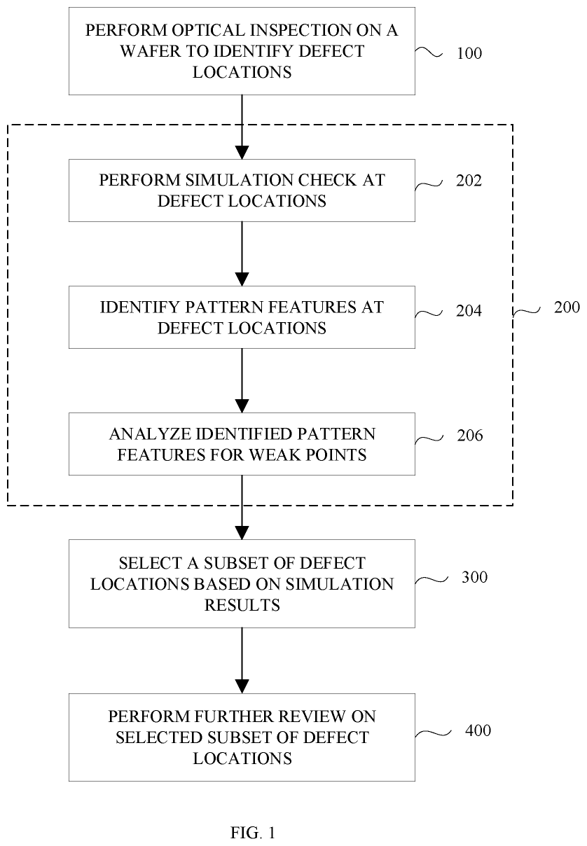

FIG. 1 is a flow chart illustrating a method for defect inspection of semiconductor wafers during the manufacturing process, according to an embodiment. A wafer may be provided; the wafer having a plurality of integrated circuits fabricated thereupon a substrate. The plurality of integrated circuits may be partially processed or may have completed the manufacturing process to form a plurality of semiconductor chips.

Those skilled in the art should readily appreciate that the term “partially processed integrated circuits” refers to integrated circuits on a semiconductor wafer during any of the various stages of semiconductor product manufacturing to form a variety of different semiconductor devices, including, but not limited to, logic devices, memory devices, etc., and the devices may be either NFET or PFET devices.

A defect inspection method for downselection of defects detected from the optical inspection for further review and analysis may be provided in FIG. 1, according to an embodiment of the disclosure. In operation 100, the wafer may undergo an optical inspection at a defect inspection stage. The optical inspection may be performed on the entire wafer surface or user-specified areas. The optical inspection may detect defects on the wafer surface and provide graphic data and position coordinates (X, Y) of those defects. The position coordinates of the defects determined from the optical inspection may be correlated to the circuit layouts of the plurality of integrated circuits on the wafer.

Optical inspections provide a relatively high throughput, which may be advantageous for line monitoring purposes during the manufacturing process. In an embodiment of the disclosure, the optical inspection performed is a bright-field inspection. The bright-field inspection may provide a graphical resolution of about 20 nm to 1000 nm.

Typically, the number of defects identified from an optical inspection is large. As an optical inspection uses a light source to locate defects on a wafer surface by detecting photons, either by reflected light or scattered light, there may be a combination of real defects and false defects, also referred to as noise, in the pool of identified defects. The number of defects generally increases as the pattern feature sizes decrease to an ever-smaller fraction of the optical wavelengths used during the optical inspection.

Additionally, for pattern features having nanoscale dimensions, the micro-roughness of the wafer surface may further contribute a portion of noise from the optical inspection. For example, projected light from an optical inspection system may be reflected or scattered from the wafer surface. Increased noise may potentially overshadow the real defects, increasing the risk of real defects escaping detection and negatively impact production yield and product reliability.

Due to the technological limitations of an optical inspection system, the graphic data of the defects may not provide a sufficiently high graphical resolution for an effective review and analysis of the identified defects. Due to the large number of defects identified from the optical inspection, it may be impractical to perform a further review and analysis of all the identified defects.

Therefore, it may be beneficial to select a subset of defects identified from the optical inspection for further review and analysis. It is important that the selected defects are real defects, and preferably critical defects, for an effective defect review process.

In operation 200, a pattern simulation may be performed on the circuit layouts of the integrated circuits at the locations corresponding to the defect locations identified from the optical inspection. The pattern simulation may be performed using pattern simulator software configured to perform a computer-implemented simulation.

The pattern simulation may include a simulation check at step 202 which may be based on pre-determined criteria. The criteria may be provided by the user or built-in as part of the simulation. The simulation check may run through the locations on the circuit layouts corresponding to all the defect locations.

Upon performing the simulation check at step 202, pattern features of the circuit layouts at those corresponding defect locations may be identified in step 204. In an embodiment of the disclosure, the number of identified pattern features is less than the number of defects identified from the optical inspection. As there may be a combination of real defects and false defects in the pool of identified defects from the optical inspection, those defect locations that do not correspond to a pattern feature in the circuit layouts may be eliminated at step 204.

At step 206, the identified pattern features may be analyzed for weak points. The analysis may be based on pre-determined criteria that are provided by the user or built-in as part of the simulation. In an embodiment of the disclosure, the pattern features having weak points may include systematic defects that are due to the interaction of the circuit layouts and the manufacturing process. Simulated pattern features may be generated from the pattern features that have weak points, where the pattern simulation attempts to rectify those weak points in the pattern features. In an embodiment of the disclosure, the number of simulated pattern features generated from step 206 is less than the number of identified pattern features at step 204. It is understood that steps 202 to 206 of operation 200 may be performed simultaneously or in rapid succession.

In an embodiment of the disclosure, the pattern simulation may include an optical proximity correction (OPC) simulation. The OPC simulation is typically applied to circuit layouts before mask-making to improve imaging quality and minimizing non-linearity in pattern transfer from the mask to the wafer during the manufacturing process.

The OPC simulation is a pattern feature enhancement technique used to compensate the pattern features for imaging errors caused by optical proximity effects. The OPC simulation may include a rule-based algorithm (using pre-determined look-up tables based on width and spacing between features) or a model-based algorithm (using compact models to dynamically simulate the final pattern). The OPC simulation may identify pattern features in the circuit layouts having potential weak points, and present simulated pattern features having different optical proximity corrections applied. The optical proximity corrections may include, but are not limited to, line-width bias corrections, corner rounding corrections, or line-end pull-back corrections.

As the OPC simulation identifies pattern features having weak points that require optical proximity corrections, the proximity-corrected pattern features are potentially systematic defects among the pool of defects identified from the optical inspection. It may be expected that the pattern features in the circuit layouts that have no optical proximity corrections applied are potentially false defects at the corresponding defect locations. Accordingly, the number of defects from the optical inspection requiring further review and analysis may be advantageously reduced.

In another embodiment of the disclosure, the pattern simulation may include an optical rule checking (ORC) technique. The ORC technique provides simulation on the pattern features of the circuit layouts at the corresponding defect locations to identify potential weak points in the pattern features that are affected by edge placement errors and/or present critical failures, such as but not limited to, bridging, pinching, or enclosure. The ORC technique may be based on one or more process-related parameters and/or user-set tolerances. The pattern features that fail the ORC technique may be flagged for further review.

The ORC technique may be performed after the OPC simulation as the ORC technique advantageously validates the result of the proximity-corrected features from the OPC simulation that may otherwise impact production yield and product reliability. However, the ORC technique may also be performed on the defect locations without the defect locations first going through an OPC simulation.

Additionally, the ORC technique may take into consideration the manufacturability of a pattern feature, also referred to as design for manufacturability or design for manufacturing (DFM). DFM is an engineering practice where guidelines may be set for DFM practices. These DFM guidelines help to define various tolerances, rules, and common manufacturing checks related to DFM. The DFM guidelines may provide a set of methodologies including recommended design rules regarding the shapes and polygons of pattern features in the circuit layouts. These parameters may indicate the manufacturability of the pattern features in the circuit layouts and those pattern features that exhibit poor manufacturability may be identified for further review.

In an embodiment of the disclosure, the pattern simulation may be performed on a circuit layout area of about 2 um by 2 um. The simulated pattern area is preferably at a central portion of the circuit layouts at the corresponding defect locations, such that peripheral effects around the simulated pattern area may be minimized. In an embodiment of the disclosure, the pattern simulation may provide a graphical resolution of about 1 nm to 20 nm.

Even though pattern simulations, such as OPC simulation and ORC technique, are typically applied to circuit layouts before mask making, the pattern simulation performed during the pre-mask fracturing stage is part of a standard quality check procedure. It will be appreciated by those skilled in the art that the pattern simulation applied at the defect inspection stage may include pattern simulations that are otherwise not performed during the pre-mask fracturing stage. For example, the pattern simulation performed at the defect inspection stage may include OPC simulation having parameters with heightened thresholds to improve defect detection. In another example, the pattern simulation may include checks that are not part of the pre-mask fracturing stage, such as but not limited to, a three-dimensional (3D) simulation based on a photoresist model used in a lithography process.

The 3D simulation may be part of the OPC simulation to build resist profile information into the OPC model-based algorithms. The 3D simulation, unlike 2D simulations, is able to simulate 3D parameters, such as resist heights, and advantageously models 3D photoresist profiles to optimize the printing of mask pattern onto the wafer for use as an etch mask in a subsequent manufacturing process. The pattern features that fail the 3D simulation may be flagged for further review.

It is noted that the associated cost of performing the pattern simulation at the defect inspection stage, both in terms of expense and time, is expected to be low. Unlike the pattern simulation that is performed during the pre-mask fracturing stage, the pattern simulation performed during the defect inspection stage may not apply to the entire circuit layouts of the integrated circuits. The pattern simulation may be performed on the corresponding defect locations that the optical inspection has identified. Therefore, the total area required to perform the pattern simulation is expected to be notably small, saving precious computing resources and time. Accordingly, the associated cost of identifying pattern features having weak points is expected to be low.

In operation 300, a subset of simulated pattern features identified from step 206 of operation 200 may be selected for further review and analysis at the corresponding defect locations on the wafer. The selection may be based on pre-determined criteria that are provided by the user. The simulated pattern features may be compared according to an inspection metric, according to an embodiment of the disclosure. The inspection metric may provide further downsizing of the number of defects for an effective review and analysis, when necessary, thereby allowing for a reasonable defect review duration. The inspection metric may provide a ranking of the simulated pattern features according to their potential contribution to yield loss or their potential contribution to impact product reliability. The inspection metric may further include indicators from DFM guidelines, such as types of pattern features and critical dimensions of pattern features that are known to be high-risk pattern features that may impact product quality. The inspection metric may yet further include a user-input criterion to identify potentially high-risk pattern features.

In operation 400, the defect locations corresponding to the subset of simulated pattern features selected from operation 300 may undergo further review and analysis using a second inspection system that has a higher graphical resolution than the optical inspection system. For example, the second inspection system may be an e-beam inspection system, according to an embodiment of the disclosure. The e-beam inspection system may include a SEM inspection apparatus or a TEM inspection apparatus that are capable of providing high graphical resolution of defects that may be otherwise too small for optical inspections. The pattern features to be inspected may be selected from simulated pattern features obtained from the pattern simulation, or selected from the pool of defects obtained from the optical inspection.

The wafer inspected at operation 100 may be reviewed using the e-beam inspection system at the corresponding position coordinates of the subset of simulated pattern features to determine if that location on the wafer presents a systematic defect or a false defect. Even though the e-beam inspection system has a much lower throughput than an optical inspection system, the number of defects to be inspected has been reduced in operations 200 and 300, enabling a more effective defect review process with highly selective defect sites.

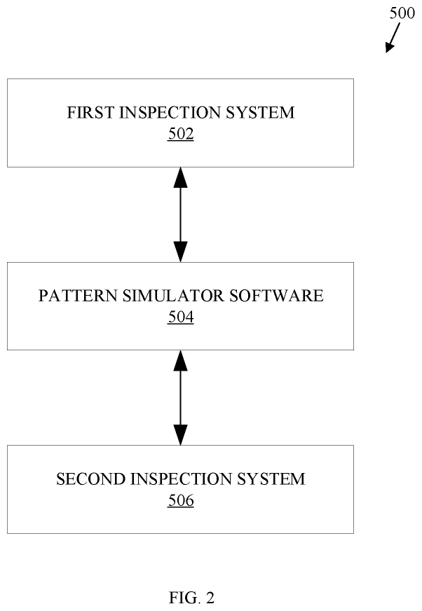

FIG. 2 illustrates a defect inspection system 500 for semiconductor wafers, according to an embodiment of the disclosure. The defect inspection system 500 may include a first inspection system 502. The first inspection system 502 may be capable of identifying a plurality of defects on a wafer and obtaining position coordinates thereto. In an embodiment of the disclosure, the first inspection system 502 may include an optical inspection system. In another embodiment of the disclosure, the first inspection system 502 may include a bright-field microscope.

The defect inspection system 500 may further include pattern simulation software 504. The pattern simulation software 504 may be capable of generating a set of simulated pattern features from circuit layouts of the integrated circuits of the semiconductor chips. The pattern simulation software 504 is provided with a circuit layout of the wafer inspected by the first inspection system 502 such that the position coordinates of the plurality of defects identified from the first inspection system 502 may be correlated to a plurality of locations in the circuit layout of the wafer.

A pattern simulation may be performed at the plurality of locations in the circuit layout of the wafer using the pattern simulator software 504 that is configured to perform a computer-implemented simulation. The pattern simulation software 504 may be capable of performing an optical proximity correction simulation, an optical rule check technique, a three-dimensional simulation, or other pattern simulations known to those skilled in the art.

Pattern features of the circuit layout at the corresponding defect locations may be identified. The pattern simulation software 504 may attempt to rectify those pattern features having weak points and generates simulated pattern features that have those weak points corrected. The defect locations that do not correspond to a pattern feature in the circuit layout may be eliminated.

The defect inspection system 500 may yet further include a second inspection system 506. The second inspection system 506 may be capable of providing a higher graphical resolution of defects than the first inspection system 502. In an embodiment of the disclosure, the second inspection system 506 may include an electron beam inspection system. In another embodiment of the disclosure, the second inspection system 506 may include a scanning electron microscope or a transmission electron microscope.

The second inspection system 506 may inspect the wafer at the locations that correspond to the locations of the simulated pattern features generated from the pattern simulation software 504. Even though the second inspection system 506 generally has a much lower throughput than the first inspection system 502, the number of defects to be inspected has been reduced to those locations having simulated patterns generated by the pattern simulation software 504, enabling a more effective defect review process with highly selective defect sites.

As presented in the above disclosure, defect inspection methods of semiconductor wafers during the manufacturing process to establish an effective defect review process and systems thereto are presented. The defect inspection methods may include using defect inspection systems such as an optical inspection system and an e-beam inspection system.

A conventional defect inspection method includes optically inspecting a wafer to detect defects on the wafer surface. Due to a large number of defects detected from the optical inspection, it may be necessary to downselect the defect counts, usually by pattern classification or selecting a random sample of the defects, for further review and analysis using an e-beam inspection system that has a relatively low throughput. Such a downselection methodology used in conventional defect inspection methods may not be a robust methodology to ensure that the selected defect sites are real defects; real defects may escape from further review and analysis. Once real defects are missed, wafers with the real defects may continue with the subsequent manufacturing processes and negatively impact production yield and product reliability.

Therefore, to establish an effective defect review process, the selected defect locations for the e-beam inspection have to provide at least an acceptable level of certainty that the defect locations selected include real defects, and preferably critical defects. The presented methods of defect inspection significantly improve the detection of systematic defects by using a pattern simulation to increase the probability of identifying real defects from a pool of potential defect sites identified from the optical inspection. The defect position coordinates obtained from the optical inspection may be correlated to the position coordinates on the circuit layouts of the integrated circuits and may be processed with the pattern simulation, where the pattern features in the circuit layouts having weak points may have proximity-corrections applied to them. It may be expected that the pattern features in the circuit layouts at the defect locations that do not have optical proximity corrections applied are false defects.

As the circuit layouts at the defect locations may be simulated relatively quickly with the pattern simulation, the associated cost associated with performing the pattern simulation may be low, if not negligible, as compared to the overall cost of the defect inspection process.

Furthermore, due to the relatively fast processing of the circuit layouts with the pattern simulation, the sensitivity used in the optical inspection may be advantageously increased to improve the detection of defects. Even though an increase in optical inspection sensitivity may potentially lead to an increased generation of false defects, the relatively quick pattern simulation process may efficiently eliminate the false defects, thereby increasing the probability of locating systematic defects on the inspected wafer.

Those simulated pattern features in the circuit layouts may be further ranked according to an inspection metric to determine the manufacturability and/or risk level of those simulated pattern features that may result in yield loss and/or reduced product reliability. The high-risk pattern features may proceed for further in-depth review and analysis using the e-beam inspection system to determine the type of defects and the cause of the defects present on the inspected wafer.

Even though the probability of the simulated pattern features being systematic defects is high, there may be incidences where the simulated pattern features present false defects. Information regarding those false defects, such as types of patterns, pattern dimensions, may be provided to improve the algorithms in the pattern simulation used at the pre-mask fracturing stage and at the defect inspection stage to establish a quality feedback loop to improve simulation accuracy.

The presented methods of defect inspection establish an effective defect review process by selecting systematic defects from a pool of defects obtained from an optical inspection through the use of pattern simulations. The systematic defects identified may subsequently proceed for a further in-depth review and analysis using an e-beam inspection system to determine the types and causes of those systematic defects.

Embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read-only memory (ROM); random access memory (RAM); magnetic disk storage media; optical storage media; flash memory devices; electrical, optical, acoustical, or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

It is understood that if a method is described herein as involving a series of steps, the order of such steps as presented herein is not necessarily the only order in which such steps may be performed, and certain of the stated steps may possibly be omitted and/or certain other steps not described herein may possibly be added to the method.

Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in an embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

While several exemplary embodiments have been presented in the above detailed description of the device, it should be appreciated that a number of variations exist. It should further be appreciated that the embodiments are only examples, and are not intended to limit the scope, applicability, dimensions, or configuration of the device in any way. Rather, the above detailed description will provide those skilled in the art with a convenient road map for implementing an exemplary embodiment of the device, it being understood that various changes may be made in the function and arrangement of elements and method of fabrication described in an exemplary embodiment without departing from the scope of this disclosure as set forth in the appended claims.

What is claimed is:

1. A defect inspection system, comprising:
a first inspection system capable of identifying a plurality of defect locations on an article;
a pattern simulator software capable of generating a set of simulated pattern features from the plurality of defect locations; and
a second inspection system capable of providing a higher graphical resolution of defects than the first inspection system at the defect locations corresponding to the set of simulated pattern features.

2. The defect inspection system of claim 1, wherein the pattern simulator software is configured to perform a computer-implemented simulation.

3. The defect inspection system of claim 2, wherein the computer-implemented simulation performs the simulation on a circuit layout of the article at locations corresponding to the plurality of defect locations on the article.

4. The defect inspection system of claim 1, wherein the second inspection system comprises an electron beam inspection system.

5. A defect inspection method, comprising:
determining a plurality of defect locations on an article;
generating a set of simulated pattern features from the plurality of defect locations;
selecting a subset of simulated pattern features from the set of simulated pattern features; and
inspecting the article at the defect locations corresponding to the subset of simulated pattern features.

6. The defect inspection method of claim 5, wherein the generation of the set of simulated pattern features comprises performing a simulation on pattern features in a circuit layout of the article.

7. The defect inspection method of claim 6, wherein the simulation comprises an optical proximity correction simulation.

8. The defect inspection method of claim 6, wherein the simulation comprises an optical rule check technique.

9. The defect inspection method of claim 6, wherein the simulation comprises a three-dimensional simulation based on a photoresist model.

10. The defect inspection method of claim 5, wherein the selection of the subset of simulated pattern features comprises ranking the set of simulated pattern features and selecting the subset of simulated features based on the ranking.

11. The defect inspection method of claim 10, wherein the ranking of the set of simulated pattern features comprises comparing the set of simulated pattern features according to an inspection metric.

12. The defect inspection method of claim 11, wherein the inspection metric comprises design for manufacturing guidelines.

13. The defect inspection method of claim 5, wherein the number of determined defect locations is greater than the number of generated simulated pattern features.

14. The defect inspection method of claim 5, wherein the determination of the plurality of defect locations comprises using an optical inspection system.

15. The defect inspection method of claim 5, wherein the inspection of the article at the defect locations corresponding to the subset of simulated pattern features comprises using an electron beam inspection system.

16. A defect inspection method, comprising:
performing a first inspection on an article to determine a plurality of defects and obtain position coordinates thereto;
correlating the position coordinates of the plurality of defects to a circuit layout of the article;
performing a simulation on the circuit layout at the corresponding defect position coordinates to obtain a set of simulated pattern features;
selecting a subset of simulated pattern features from the set of simulated pattern features; and
performing a second inspection on the article at the position coordinates corresponding to the subset of simulated pattern features.

17. The defect inspection method of claim 16, wherein the selection of the subset of simulated pattern features comprises ranking the set of simulated pattern features according to an inspection metric based on simulation results.

18. The defect inspection method of claim 16, wherein the second inspection provides a higher graphical resolution than the first inspection.

19. The defect inspection method of claim 16, wherein the article comprises a wafer having an at least partially processed integrated circuit.

20. The defect inspection method of claim 16, further comprising increasing a sensitivity of the first inspection when identifying the plurality of defects.
